(19) United States
(12) Patent Application Publication
(10) Pub. No.: US 2022/0213594 A1
(43) Pub. Date: Jul. 7, 2022

(54) PROCESS MODULE, SUBSTRATE PROCESSING SYSTEM, AND PROCESSING METHOD

(71) Applicant: Tokyo Electron Limited, Tokyo (JP)

(72) Inventor: Takayuki YAMAGISHI, Tokyo (JP)

(21) Appl. No.: 17/645,829

(22) Filed: Dec. 23, 2021

(30) Foreign Application Priority Data
Jan. 5, 2021 (JP) 2021-000572

(51) Int. Cl. C23C 16/458; H01J 37/32; H01L 21/677; H01L 21/687

(52) U.S. Cl. CPC C23C 16/4584; H01J 37/32733; H01L 21/68707; H01J 2237/20228; H01J 2237/3321; H01L 21/67754

(57) ABSTRACT

A process module includes four stages arranged in a two-row and two-column layout inside the process module, wherein a row interval and a column interval that constitute the two-row and two-column layout have different dimensions.

### CROSS-REFERENCE TO RELATED APPLICATION

This application is based upon and claims the benefit of priority from Japanese Patent Application No. 2021-000572, filed on Jan. 5, 2021, the entire contents of which are incorporated herein by reference.

### TECHNICAL FIELD

The present disclosure relates to a process module, a substrate processing system, and a processing method.

### BACKGROUND

As a process module that performs a process on a substrate (hereinafter, also referred to as a “wafer”) in a substrate processing system, a process module in which four wafers are processed simultaneously in one chamber is known (Patent Document 1).

### PRIOR ART DOCUMENT

### Patent Document

Patent Document 1: Japanese Laid-Open Patent Publication No. 2019-087576

### SUMMARY

According to one embodiment of the present disclosure, there is provided a process module including four stages arranged in a two-row and two-column layout inside the process module, wherein a row interval and a column interval that constitute the two-row and two-column layout have different dimensions.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view illustrating an example of a configuration of a substrate processing system in an embodiment of the present disclosure.

FIG. 2 is an exploded perspective view illustrating an example of a configuration of a substrate processing apparatus in an embodiment.

FIG. 3 is a view illustrating an example of a positional relationship between a processing space and a rotation arm at a standby position.

FIG. 4 is a view illustrating an example of a positional relationship between the processing space and the rotation arm at a wafer holding position.

FIG. 5 is a view illustrating an example of a movement path of wafers in the substrate processing apparatus in the embodiment.

FIG. 6 is a view illustrating an example of an exhaust path of the substrate processing apparatus in the embodiment.

FIG. 7 is a schematic cross-sectional view illustrating an example of a configuration of the substrate processing apparatus in the embodiment.

### DETAILED DESCRIPTION

Hereinafter, embodiments of a process module, a substrate processing system, and a processing method disclosed herein will be described in detail with reference to the drawings. The technology disclosed herein is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A process module in which four wafers are processed simultaneously in one chamber includes four stages on which the four wafers are placed, respectively. This results in an increase in footprint. However, in a factory in which a substrate processing system is installed, it is required to reduce the footprint in order to improve space efficiency. In addition, there may be a case in which a process module in which two wafers are processed simultaneously in one chamber is connected to a vacuum transfer chamber through which the wafer is loaded into or unloaded from the process module. That is, process modules of different sizes may be connected to the vacuum transfer chamber. In such a case, a wafer transfer mechanism corresponding to each of the process modules of different sizes is provided in the vacuum transfer chamber. Therefore, it is required to reduce the footprint of the process module and to share the wafer transfer mechanism.

### Embodiment

### [Configuration of Substrate Processing System]

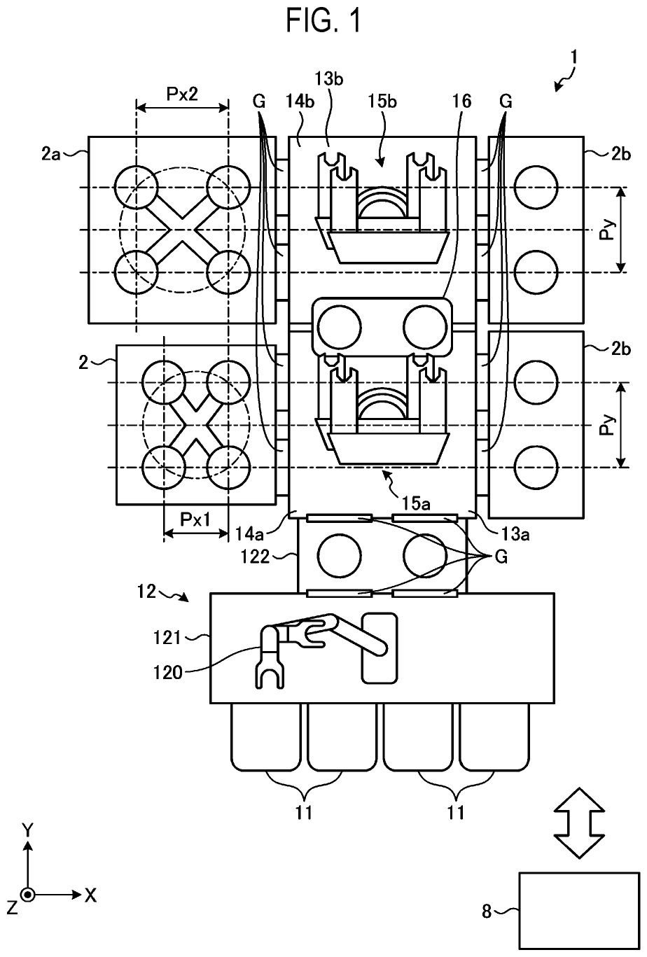

FIG. 1 is a schematic plan view illustrating an example of a configuration of a substrate processing system in an embodiment of the present disclosure. A substrate processing system 1 illustrated in FIG. 1 includes loading/unloading ports 11, a loading/unloading module 12, vacuum transfer modules 13a and 13b, and substrate processing apparatuses 2, 2a, and 2b. In FIG. 1, the X direction will be referred to as a left-right direction, the Y direction will be referred to as a front-rear direction, the Z direction will be referred to as an up-down direction (height direction), and the side having the loading/unloading ports 11 will be referred to as a front side in the front-rear direction. The loading/unloading ports 11 are connected to the front side of the loading/unloading module 12, and the vacuum transfer module 13a is connected to the rear side of the loading/unloading module 12 in the front-rear direction.

Carriers, which are transfer containers accommodating substrates to be processed, are placed on the loading/unloading ports 11, respectively. The substrate is a wafer W, which is a circular substrate having a diameter of, for example, 300 mm. The loading/unloading module 12 is a module configured to perform loading/unloading of the wafers W between the carriers and the vacuum transfer module 13a. The loading/unloading module 12 includes a normal-pressure transfer chamber 121 in which the wafers W are delivered to and from the carriers in a normal-pressure atmosphere by a transfer mechanism 120, and a load-lock chamber 122 in which the atmosphere in which the wafers W are placed is switched between the normal-pressure atmosphere and a vacuum atmosphere.

The vacuum transfer modules 13a and 13b have vacuum transfer chambers 14a and 14b, respectively, in which a vacuum atmosphere is formed. Substrate transfer mechanisms 15a and 15b are disposed inside the vacuum transfer chambers 14a and 14b, respectively. Between the vacuum transfer module 13a and the vacuum transfer module 13b, a path 16 in which the delivery of the wafer W is performed between the vacuum transfer modules 13a and 13b is disposed. Each of the vacuum transfer chambers 14a and 14b is formed in, for example, a rectangular shape in a plan view. The substrate processing apparatuses 2 and 2b are respectively connected to sides facing each other in the left-right direction among the four sidewalls of the vacuum transfer chamber 14a. The substrate processing apparatuses 2a and 2b are respectively connected to sides facing each other in the left-right direction among four sidewalls of the vacuum transfer chamber 14b.

The load-lock chamber 122 installed in the loading/unloading module 12 is connected to the front side among the four sidewalls of the vacuum transfer chamber 14a. Gate valves G are arranged between the normal-pressure transfer chamber 121 and the load-lock chamber 122, between the load-lock chamber 122 and the vacuum transfer module 13a, and between the vacuum transfer modules 13a and 13b and the substrate processing apparatuses 2, 2a, and 2b, respectively. Each gate valve G opens and closes the loading/unloading port for the wafer W, which is provided between the modules connected to each other.

The substrate transfer mechanism 15a transfers the wafers W among the loading/unloading module 12, the substrate processing apparatuses 2 and 2b, and the path 16 in a vacuum atmosphere. In addition, the substrate transfer mechanism 15b transfers the wafers W between the path 16 and the substrate processing apparatuses 2a and 2b in a vacuum atmosphere. Each of the substrate transfer mechanisms 15a and 15b is configured with an articulated arm, and includes a substrate holder configured to hold the wafer W. Each of the substrate processing apparatuses 2, 2a, and 2b collectively processes a plurality of (e.g., two or four) wafers W using a process gas in a vacuum atmosphere. To do this, the substrate holder of each of the substrate transfer mechanisms 15a and 15b is configured to be capable of simultaneously holding, for example, two wafers W to collectively deliver the two wafers W to the substrate processing apparatus 2, 2a, or 2b. The substrate processing apparatuses 2 (or 2a) may be configured to use a rotation arm provided therein, and transfer the wafer W received by an outer stage located close to the vacuum transfer module 13a (or 13b) to an inner stage. Each of the substrate transfer mechanisms 15a and 15b is an example of a wafer transfer mechanism.

In the substrate processing apparatuses 2, 2a, and 2b, a pitch Py between the stages in the Y direction (row interval) is the same. Thus, the substrate processing apparatuses 2, 2a, and 2b can be connected to any locations of the sides of the vacuum transfer modules 13a and 13b, which are opposite to each other in the left-right direction. In the example of FIG. 1, the substrate processing apparatus 2 and the substrate processing apparatus 2b are connected to the vacuum transfer module 13a, and the substrate processing apparatus 2a and the substrate processing apparatus 2b are connected to the vacuum transfer module 13b. The substrate processing apparatus 2 and the substrate processing apparatus 2a differ from each other in the diameter of a reactor including a processing space corresponding to one stage according to a process application, and thus have different pitches Px1 and Px2, which are pitches between the stages in the X direction (column interval), respectively. In the substrate processing apparatus 2a, the pitch Px2 has the same value as the pitch Py. That is, the pitch Py corresponds to the size of the largest reactor. That is, since the size of the reactor of the substrate processing apparatus 2 is smaller than that of the substrate processing apparatus 2a, the pitch Px1 may be set to be smaller than the pitch Px2.

An internal configuration of the substrate processing apparatus 2a is essentially identical to that of the substrate processing apparatus 2, except that the pitch Px2 is different from the pitch Px1, and a description thereof will be omitted. The substrate processing apparatus 2b has two stages and is configured to simultaneously load two wafers thereinto to perform processing on the two wafers, and simultaneously unload the processed two wafers therefrom, rather than performing the transfer of the wafers W therein. For the sake of convenience in the description, in the XYZ coordinate system illustrated in FIG. 1, the pitch in the X direction is defined as the column interval, and the pitch in the Y direction is defined as the row interval. However, for example, the substrate processing apparatuses 2 (or 2a) may be disposed at the inner side of the vacuum transfer module 13b. In this case, it is necessary to consider changing the column interval and the row interval. That is, it is necessary to consider which is the row and which is the column based on the surfaces of the substrate processing apparatuses 2 and 2a that are in contact with the vacuum transfer modules 13a and 13b, respectively.

The substrate processing system 1 includes a controller 8. The controller 8 is, for example, a computer including a processor, a storage part, an input device, a display device, and the like. The controller 8 controls each part of the substrate processing system 1. With the controller 8, an operator may perform a command input operation or the like using the input device in order to manage the substrate processing system 1. In addition, under the control of the controller 8, the operation state of the substrate processing system 1 may be visually displayed on the display device. In addition, the storage part of the controller 8 stores a control program, recipe data, and the like used by the processor to control various processes to be executed by the substrate processing system 1. The processor of the controller 8 executes the control program to control each part of the substrate processing system 1 according to the recipe data, whereby desired substrate processing is executed in the substrate processing system 1.

### [Configuration of Substrate Processing Apparatus]

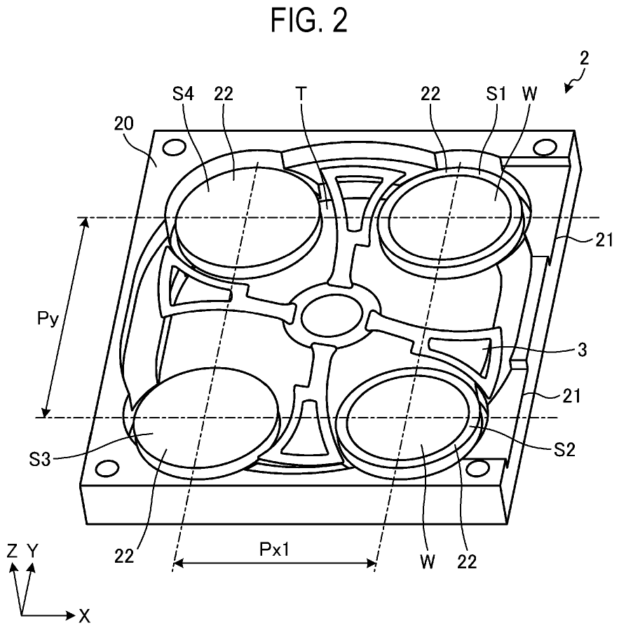

Next, an example in which the substrate processing apparatus 2 is applied to, for example, a film forming apparatus that performs a plasma chemical vapor deposition (CVD) process on wafers W will be described with reference to FIGS. 2 to 7. A substrate processing apparatus 2 is an example of a process module. FIG. 2 is an exploded perspective view illustrating an example of a configuration of a substrate processing apparatus in the present embodiment. As illustrated in FIG. 2, the substrate processing apparatus 2 includes a processing container (vacuum container) 20 having a rectangular shape in a plan view. The processing container 20 is configured to keep the interior thereof in a vacuum atmosphere. The processing container 20 is defined by closing an upper opening portion with a gas supplier 4 and a manifold 36 to be described later. In FIG. 2, internal partition walls and the like are omitted such that a relationship between a plurality of processing spaces S1 to S4 and a rotation arm 3 can be easily understood. The processing container 20 includes two loading/unloading ports 21 formed in the side surface thereof connected to the vacuum transfer chamber 14a (or 14b) and arranged in the Y direction. The loading/unloading ports 21 are opened and closed by the gate valves G, respectively.

The plurality of processing spaces S1 to S4 are provided inside the processing container 20. A stage 22 is arranged in each of the processing spaces S1 to S4. The stage 22 is movable vertically. Specifically, the stage 22 moves upward when the wafer W is processed, and moves downward when the wafer W is transferred. Under the processing spaces S1 to S4, a transfer space T in which the wafers W are transferred by the rotation arm 3 is provided to be connected to the processing spaces S1 to S4. In addition, the transfer space under the processing spaces S1 and S2 in the transfer space T is connected to each loading/unloading port 21 so that loading/unloading of the wafers W is performed between the vacuum transfer chambers 14a and 14b by the substrate transfer mechanisms 15a and 15b.

The respective stages 22 of the processing spaces S1 to S4 are arranged in a two-row and two-column layout when viewed from the above. This layout has different dimensions in row and column intervals. That is, the pitch Py, which is a pitch in the Y-direction between the stages 22 (row interval), and the pitch Px1, which a pitch in the X-direction between the stages 22 (column interval), have a relationship of Py>Px1.

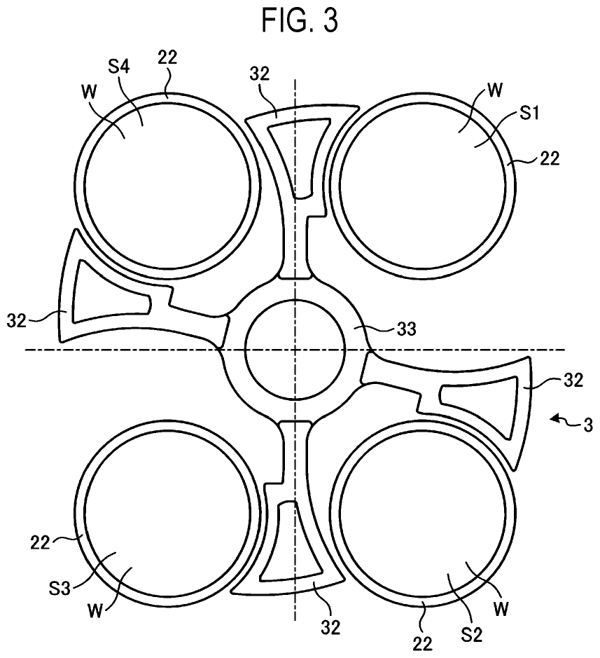

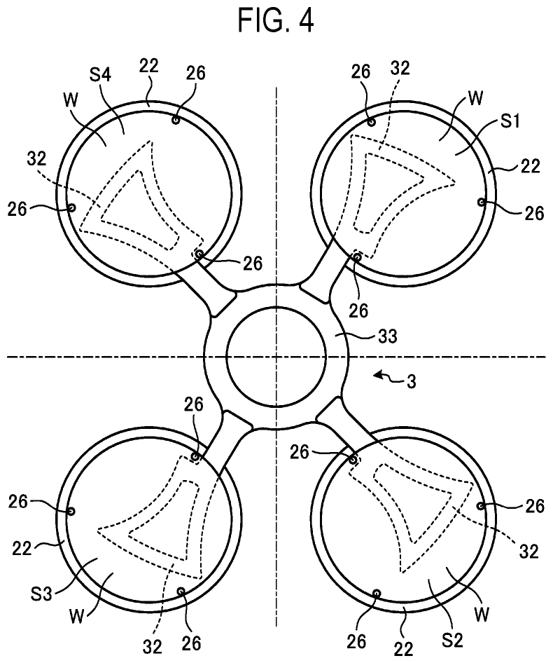

FIG. 3 is a view illustrating an example of a positional relationship between the processing spaces and the rotation arm at a standby position. FIG. 4 is a view illustrating an example of a positional relationship between the processing spaces and the rotation arm at a wafer holding position. As illustrated in FIGS. 3 and 4, the rotation arm 3 has four end effectors 32 capable of holding the wafers W to be placed on the stages 22, respectively, and a base member 33 having a rotation axis at the center position of the two-row and two-column layout. The four end effectors 32 are connected to the base member 33 to form an X shape. The X shape of the rotation arm 3 has a configuration in which a dimension in the Y direction, which corresponds to the row interval of the X shape, and a dimension in the X direction, which corresponds to the column interval of the X shape, are different from each other at the wafer holding position illustrated in FIG. 4.

At the standby position illustrated in FIG. 3, the rotation arm 3 is disposed between two adjacent processing spaces of the processing spaces S1 to S4, so that the rotation arm 3 do not interfere with the vertical movement of each stage 22. FIG. 3 illustrates the state in which the wafer W is placed on each stage 22. A description will be made as to the movement of the rotation arm 3 when the wafers W are transferred such that the wafers W in the first column and the wafers W in the second column are interchanged from this state, that is, when the wafers W in the processing spaces S1 and S2 are transferred to the processing spaces S3 and S4, and the wafers W in the processing spaces S3 and S4 are transferred to the processing spaces S1 and S2.

First, respective stages 22 are moved to delivery positions in the transfer space T at the lower side, and lift pins 26 (to be described later) provided on the respective stages 22 are raised to lift the wafers W. Subsequently, the rotation arm 3 is rotated clockwise by about 30 degrees to insert respective end effectors 32 between the stages 22 and the wafers W as illustrated in FIG. 4. Subsequently, the lift pins 26 are lowered to place the wafers W on respective end effectors 32. Subsequently, the rotation arm 3 is rotated clockwise by 180 degrees to transfer the wafers W to holding positions on respective stages 22. When the respective stages 22 raise the lift pins 26 to receive the wafers W, the rotation arm 3 is rotated counterclockwise by about 30 degrees to move to the standby position. In this way, the wafers W can be transferred by the rotation arm 3 such that the wafers W in the first column and the wafers W in the second column are interchanged with each other. Therefore, for example, when different processes are repeated in the processing spaces S1 and S2 and the processing spaces S3 and S4 (e.g., when a film forming process and an annealing process are repeated), the time required to transfer the wafers W can be reduced.

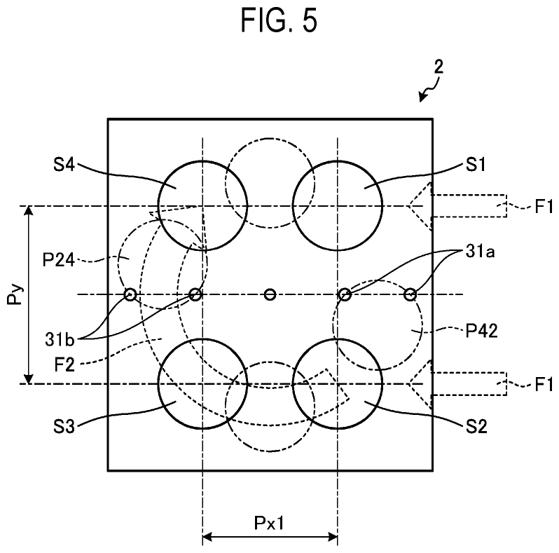

FIG. 5 is a view illustrating an example of wafer movement paths in the substrate processing apparatus in the present embodiment. In FIG. 5, the movement paths when the wafers W are transferred from the vacuum transfer chamber 14a to the interior of the substrate processing apparatus 2 will be described. First, by the substrate transfer mechanism 15a of the vacuum transfer chamber 14a, as illustrated by a path F1, at the delivery positions of the transfer space T under the processing spaces S1 and S2 corresponding to the stages 22 in the same column, two wafers W are simultaneously loaded into respective stages 22. The respective stages 22 of the processing spaces S1 and S2 raise the lift pins 26 to receive the wafers W.

Subsequently, the rotation arm 3 is rotated clockwise from the standby position by about 30 degrees, the end effectors 32 are inserted between the stages 22 located at the delivery positions under the processing spaces S1 and S2 and the wafers W, respectively, and the lift pins 26 are lowered to place the wafers W on the respective end effectors 32. When the wafers W are placed, the rotation arm 3 is rotated clockwise by 180 degrees as illustrated by a path F2 to transfer the wafers W onto the stages 22 located at the delivery positions (the holing positions of the rotation arm 3) of the transfer space T under the processing spaces S3 and S4. When the stages 22 located at the delivery positions under the processing spaces S3 and S4 raise the lift pins 26 to receive the wafers W, respectively, the rotation arm 3 is rotated counterclockwise by about 30 degrees to move to the standby position. In this state, no wafers W are placed on the stages 22 of the processing spaces S1 and S2, but the wafers W are placed on the stages 22 of the processing spaces S3 and S4. Subsequently, as illustrated by the path F1, two wafers W are simultaneously loaded into respective stages 22 at the delivery positions located under the processing spaces S1 and S2 by the substrate transfer mechanism 15a of the vacuum transfer chamber 14a, and the wafers W are placed on the stages 22 of the processing spaces S1 and S2, whereby the wafers W are placed on all of the stages 22 of the processing spaces S1 to S4, respectively.

Similarly, during unloading, the wafers W placed on the stages 22 located at the delivery positions under the processing spaces S1 and S2 are first transferred to the vacuum transfer chamber 14a by the substrate transfer mechanism 15a. Subsequently, the wafers W placed on the stages 22 located at the delivery positions under the processing spaces S3 and S4 are transferred by the rotation arm 3 to the stages 22 located at the delivery positions under the processing spaces S1 and S2. Subsequently, the wafers W placed on the stages 22 located at the delivery positions under the processing spaces S1 and S2 are transferred to the vacuum transfer chamber 14a by the substrate transfer mechanism 15a. In this way, by using the substrate transfer mechanism 15a capable of simultaneously transferring two wafers W and the rotation arm 3, the wafers W can be loaded into and unloaded from the processing spaces S1 to S4.

When the rotation arm 3 transfers the wafers W, the deviations of the wafers W from the stages 22 of a transfer destination may be detected, and the stages 22 may be finely moved in the XY plane to correct the deviation of the wafers W. In this case, the substrate processing apparatus 2 includes a deviation detection sensor configured to detect the deviation of each wafer W at each of rotationally symmetric positions within the row interval or the column interval, on the rotation trajectory of the wafers W held by the rotation arm 3. In the example of FIG. 5, sensors 31a and 31b are provided between the processing spaces S1 and S2 and between the processing spaces S3 and S4, respectively, within the row interval.

Each of the sensors 31a and 31b is, for example, a set of two optical sensors, which are arranged on a straight line in the X direction that passes through the center of the substrate processing apparatus 2, that is, the center position of the two-row and two-column layout. This is to make the direction of expansion of the processing container 20 caused by a thermal expansion the same in the two sensors, thereby reducing an error. The arrangement positions of the sensors 31a and 31b are not limited to the X direction as long as the positions are on the straight line passing through the center of the substrate processing apparatus 2. The substrate processing apparatus 2 detects deviation amounts of the wafers W by comparing front and rear edges of the wafers W detected by the sensors 31a and 31b with output results of an encoder (not illustrated) provided in the rotation arm 3.

In the example of FIG. 5, a position P24 represents a state in which the rear edge of the wafer W passes through the sensor 31b when the wafer W is transferred from the processing space S2 to the processing space S4, and a position P42 represents a state in which the rear edge of the wafer W passes through the sensor 31a when the wafer W is transferred from the processing space S4 to the processing space S2. The substrate processing apparatus 2 may finely move the stages 22 within the XY plane according to a detected deviation amount to correct the deviations of the wafers W. That is, the substrate processing apparatus 2 adjusts the deviations such that the wafers W are located at the centers of the processing spaces S1 to S4, respectively, when the stages 22 are raised. The term “finely” used herein refers to about 5 mm or less.

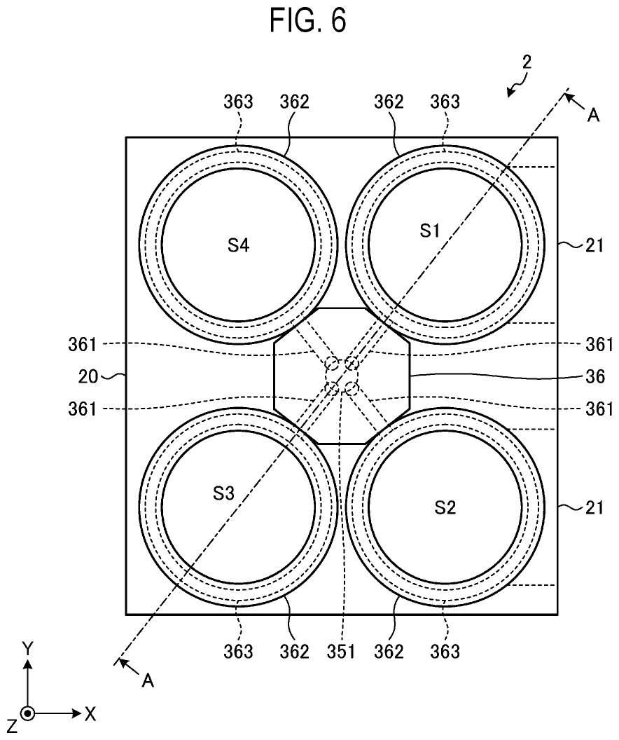

FIG. 6 is a view illustrating an example of exhaust paths of the substrate processing apparatus in the present embodiment. FIG. 6 illustrates a case in which the processing container 20 is viewed from above in the state in which the gas supplier 4 (to be described later) is removed. As illustrated in FIG. 6, a manifold 36 is arranged in the center of the substrate processing apparatus 2. The manifold 36 includes a plurality of exhaust paths 361, which are connected to the processing spaces S1 to S4, respectively. Each exhaust path 361 is connected to a hole 351 in a thrust nut 35 (to be described later) below the center of the manifold 36. Each exhaust path 361 is connected to an annular flow path 363 in each of the guide members 362 provided above the processing spaces S1 to S4. That is, the gas in the processing spaces S1 to S4 is exhausted to a joined exhaust port 205 (to be described later) via the flow path 363, the exhaust paths 361, and the hole 351.

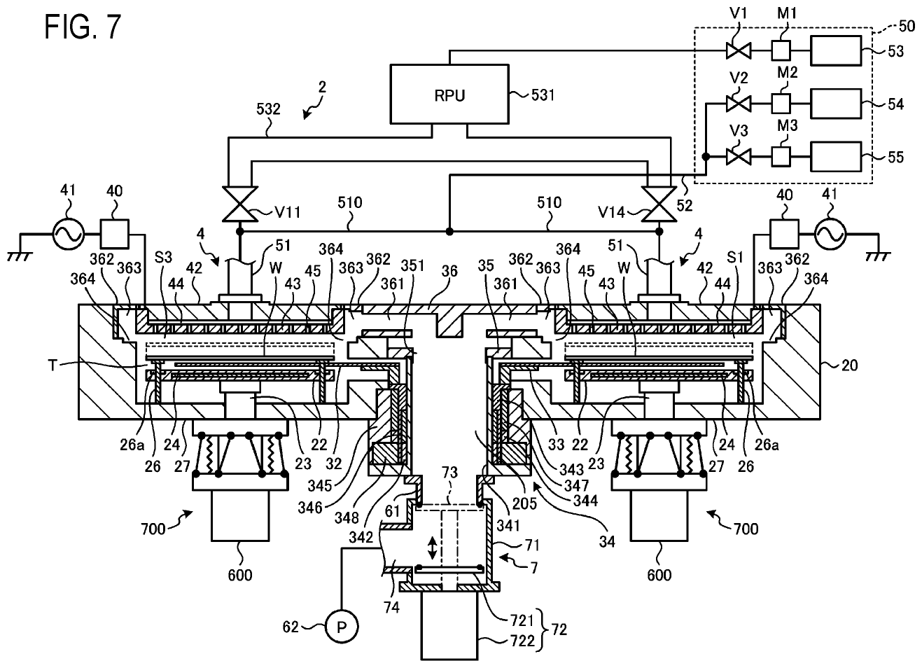

FIG. 7 is a schematic cross-sectional view illustrating an example of a configuration of the substrate processing apparatus in the present embodiment. The cross section of FIG. 7 corresponds to the cross section of the substrate processing apparatus 2 taken along line A-A in FIG. 6. The four processing spaces S1 to S4 are configured in the same manner as each other, and are formed between the stages 22, on each of which the wafer W is placed, and the gas suppliers 4 disposed to face the stages 22, respectively. In other words, in the processing container 20, the stage 22 and the gas supplier 4 are provided for each of the four processing spaces S1 to S4. FIG. 7 illustrates the processing spaces S1 and S3. Hereinafter, the processing space S1 will be described as an example.

The stage 22 also serves as a lower electrode, is made of, for example, a metal or aluminum nitride (AlN) in which a metal mesh electrode is embedded, and is formed in a flat column shape. The stage 22 is supported by a support member 23 from the bottom side. The support member 23 is formed in a cylindrical shape, extends vertically downward, and penetrates a bottom 27 of the processing container 20. A lower end portion of the support member 23 is located outside the processing container 20 and connected to a rotational driving mechanism 600. The support member 23 is rotated by the rotational driving mechanism 600. The stage 22 is configured to be rotatable with the rotation of the support member 23. An adjustment mechanism 700 is provided at the lower end portion of the support member 23 to adjust the position and inclination of the stage 22. The stage 22 is configured to be capable of being raised and lowered between a processing position and a delivery position using the support member 23 by the adjustment mechanism 700. In FIG. 7, the stage 22 located at the delivery position is indicated by the solid line, and the stage 22 located at the processing position is indicated by the broken line. In addition, at the delivery position, the end effector 32 is inserted between the stage 22 and the wafer W to receive the wafer W from the lift pins 26. The processing position is a position when substrate processing (e.g., a film forming process) is executed, and the delivery position is a position at which the wafer W is delivered to and from the substrate transfer mechanism 15a or the end effector 32.

A heater 24 is embedded in each stage 22. The heater 24 heats each wafer W placed on the stage 22 to, for example, about 60 degrees C. to 600 degrees C. In addition, the stage 22 is connected to a ground potential.

In addition, the stage 22 is provided with a plurality of (e.g., three) pin through-holes 26a, and the lift pins 26 are arranged inside these pin through-holes 26a, respectively. The pin through-holes 26a are provided to penetrate the stage 22 from a placement surface (top surface) of the stage 22 to a rear surface (bottom surface) opposite to the placement surface. The lift pins 26 are slidably inserted into the respective pin through-holes 26a. Upper ends of the lift pins 26 are suspended at placement-surface sides of the pin through-holes 26a. That is, the upper ends of the lift pins 26 have a diameter larger than those of the pin through-holes 26a, and recesses having a diameter and a thickness larger than those of the upper ends of the lift pins 26 are formed at the upper ends of the pin through-holes 26a to be capable of accommodating the upper ends of the lift pins 26, respectively. As a result, the upper ends of the lift pins 26 are engaged with the stage 22 and suspended at the placement-surface sides of the pin through-holes 26a, respectively. In addition, the lower ends of the lift pins 26 protrude from the rear surface of the stage 22 toward the bottom 27 of the processing container 20.

In the state in which the stage 22 is raised to the processing position, the upper ends of the lift pins 26 are received in the recesses at the placement-surface sides of the pin through-holes 26a, respectively. When the stage 22 is lowered to the delivery position from this state, the lower ends of the lift pins 26 come into contact with the bottom 27 of the processing container 20 and the lift pins 26 move in the pin through-holes 26a such that the upper ends of the lift pins 26 protrude from the placement surface of the stage 22, as illustrated in FIG. 7. In this case, the lower ends of the lift pins 26 may be configured to come into contact with, for example, a lift-pin contact member located at the bottom side, instead of the bottom 27 of the processing container 20.

The gas supplier 4 is provided in a ceiling portion of the processing container 20 and above the stage 22 via a guide member 362 made of an insulating member. The gas supplier 4 has a function as an upper electrode. The gas supplier 4 includes a lid 42, a shower plate 43 forming a facing surface provided to face the placement surface of the stage 22, and a gas flow chamber 44 formed between the lid 42 and the shower plate 43. A gas supply pipe 51 is connected to the lid 42, and gas ejection holes 45 penetrating the shower plate 43 in the thickness direction are arranged vertically and horizontally in the shower plate 43 such that the gas is ejected toward the stage 22 in the form of a shower.

Each gas supplier 4 is connected to a gas supply system 50 via a gas supply pipe 51. The gas supply system 50 includes, for example, sources of a reaction gas (a film forming gas), a purge gas, and a cleaning gas, which are processing gases, a pipe, a valve V, a flow rate adjuster M, and the like. The gas supply system 50 includes, for example, a cleaning gas source 53, a reaction gas source 54, a purge gas source 55, valves V1 to V3 provided in the pipes of respective gas sources, and flow rate adjusters M1 to M3.

The cleaning gas source 53 is connected to a cleaning gas supply path 532 via the flow rate adjuster M1, the valve V1, and a remote plasma unit (RPU) 531. The cleaning gas supply path 532 branches into four systems at the downstream side of the RPU 531 to be connected to each gas supply pipe 51. Valves V11 to V14 are provided for respective branched pipes at the downstream side of the RPU 531. The respective valves V11 to V14 are opened during cleaning. For the sake of convenience in illustration, only the valves V11 and V14 are illustrated in FIG. 7.

The reaction gas source 54 and the purge gas source 55 are connected to a gas supply path 52 via the flow rate adjusters M2 and M3 and the valves V2 and V3, respectively. The gas supply path 52 is connected to the gas supply pipe 51 via the gas supply pipe 510. In FIG. 7, the gas supply path 52 and the gas supply pipe 510 collectively illustrate respective supply paths and respective supply pipes corresponding to respective gas suppliers 4.

A radio-frequency power supply 41 is connected to the shower plate 43 via a matcher 40. The shower plate 43 has a function as an upper electrode facing the stage 22. When radio-frequency power is applied between the shower plate 43, which is the upper electrode, and the stage 22, which is the lower electrode, it is possible to plasmarize a gas supplied from the shower plate 43 to the processing space S1 (a reaction gas in this example) by capacitive coupling.

Next, the exhaust paths from the processing spaces S1 to S4 to the joined exhaust port 205 will be described. As illustrated in FIGS. 6 and 7, the exhaust paths pass through respective exhaust paths 361 from the annular flow paths 363 in respective guide members 362 provided above the processing spaces S1 to S4, and are directed to a joined exhaust port 205 via a junction portion and the hole 351 below the center of the manifold 36. The exhaust paths 361 have, for example, a circular cross section.

Around each of the processing spaces S1 to S4, a guide member 362 used for exhaust is provided to surround each of the processing spaces S1 to S4. The guide member 362 is, for example, an annular body, which is provided to surround a region around the stage 22 located at the processing position with an interval from the stage 22. The guide member 362 is configured to form therein a flow path 363 having, for example, a rectangular vertical cross section and an annular shape in a plan view. In FIG. 6, the processing spaces S1 to S4, the guide members 362, the exhaust paths 361, and the manifold 36 are schematically illustrated.

The guide members 362 form slit-shaped slit exhaust ports 364, which are open toward respective processing spaces S1 to S4. In this way, the slit exhaust ports 364 are formed in the side peripheral portions of respective processing spaces S1 to S4 in the circumferential direction. The exhaust paths 361 are connected to the flow paths 363, and the processing gas exhausted from the slit exhaust ports 364 is allowed to flow toward the junction portion and the hole 351 below the center of the manifold 36.

As illustrated in FIG. 6, the set of processing spaces S1 and S2 and the set of processing spaces S3 and S4 are arranged rotationally symmetrically by 180 degrees around the manifold 36 when viewed from the above. As a result, processing-gas flow paths extending from respective processing spaces S1 to S4 to the hole 351 via the slit exhaust ports 364, the flow paths 363 in the guide members 362, and the exhaust paths 361 are formed rotationally symmetrically by 180 degrees to surround the hole 351.

The hole 351 is connected to the exhaust pipe 61 via the joined exhaust port 205 inside a thrust pipe 341 of a biaxial vacuum seal 34 arranged in the central portion of the processing container 20. The exhaust pipe 61 is connected to a vacuum pump 62 constituting a vacuum exhaust mechanism via a valve mechanism 7. One vacuum pump 62 is provided in, for example, one processing container 20, and the exhaust pipes at the downstream sides of respective vacuum pumps 62 are joined and are connected to, for example, a factory exhaust system.

The valve mechanism 7 opens and closes the processing-gas flow path formed in each exhaust pipe 61, and includes, for example, a casing 71 and an opening/closing part 72. A first opening 73 connected to the exhaust pipe 61 located at the upstream side is formed in the top surface of the casing 71, and a second opening 74 connected to the exhaust pipe 61 located at the downstream side is formed in the side surface of the casing 71.

The opening/closing part 72 includes, for example, an opening/closing valve 721 formed to have such a size as to close the first opening 73, and a lifting mechanism 722 provided outside the casing 71 so as to raise and lower the opening/closing valve 721 inside the casing 71. The opening/closing valve 721 is configured to be capable of being raised and lowered between a closing position (indicated by the alternated long and short dash line in FIG. 7) at which the first opening 73 is closed and an opening position (indicated by the solid line in FIG. 7) displaced below the first and second openings 73. When the opening/closing valve 721 is located at the closing position, the downstream end of the joined exhaust port 205 is closed, and the exhaust of the interior of the processing container 20 is stopped. In addition, when the opening/closing valve 721 is located at the opening position, the downstream end of the joined exhaust port 205 is opened and the interior of the processing container 20 is exhausted.

Next, the bi-axial vacuum seal 34 and the thrust nut 35 will be described. The biaxial vacuum seal 34 includes a thrust pipe 341, bearings 342 and 344, a rotor 343, a main body 345, magnetic fluid seals 346 and 347, and a direct drive motor 348.

The thrust pipe 341 is a non-rotating central shaft and receives a thrust load applied to the upper center of the substrate processing apparatus 2 via the thrust nut 35. That is, the thrust pipe 341 receives a vacuum load applied to the central portion of the substrate processing apparatus 2 when the interiors of the processing spaces S1 to S4 become a vacuum atmosphere, thereby suppressing the deformation of the upper portion of the substrate processing apparatus 2. The thrust pipe 341 has a hollow structure, and the interior of the thrust pipe 341 forms the joined exhaust port 205. The top surface of the thrust pipe 341 is in contact with the bottom surface of the thrust nut 35. In addition, the inner surface of the upper portion of the thrust pipe 341 and the outer surface of a convex portion at the inner peripheral side of the thrust nut 35 are sealed by an O-ring (not illustrated).

The outer peripheral side surface of the thrust nut 35 has a screw structure, and the thrust nut 35 is screwed to a partition wall of the central portion of the processing container 20. The manifold 36 is provided above the central portion of the processing container 20. The thrust load is received by the manifold 36, the partition wall in the central portion of the processing container 20, the thrust nut 35, and the thrust pipe 341.

The bearing 342 is a radial bearing that holds the rotor 343 at the side of the thrust pipe 341. The bearing 344 is a radial bearing that holds the rotor 343 at the side of the main body 345. The rotor 343 is arranged concentrically with the thrust pipe 341 and is a rotation shaft in the center of the rotation arm 3. In addition, the base member 33 is connected to the rotor 343. When the rotor 343 rotates, the rotation arm 3, that is, the end effectors 32 and the base member 33 rotate.

The main body 345 accommodates therein the bearings 342 and 344, the rotor 343, the magnetic fluid seals 346 and 347, and the direct drive motor 348. The magnetic fluid seals 346 and 347 are arranged at the inner peripheral side and the outer peripheral side of the rotor 343, and seal the processing spaces S1 to S4 from the outside. The direct drive motor 348 is connected to the rotor 343, and drives the rotor 343 to rotate the rotation arm 3.

In this way, in the bi-axial vacuum seal 34, the thrust pipe 341, which is the central axis as a first axis that does not rotate, plays the role of a gas exhaust pipe while supporting the load of the upper portion of the processing container 20, and the rotor 343 as a second axis plays the role of rotating the rotation arm 3.

As described above, according to the embodiment, the process module (the substrate processing apparatus 2) includes the four stages 22 arranged in a two-row and two-column layout inside the process module, wherein the row interval and column interval constituting the layout have different dimensions. As a result, it is possible to reduce the footprint of the process module and share the wafer transfer mechanism.

According to the embodiment, the process module further includes the rotation arm 3 provided with the four end effectors 32, each of which is capable of holding the wafer W to be placed on each of the four stages 22, and the base member 33 having a rotation shaft located at the center position of the layout. The four end effectors 32 are connected to the base member 33 to form an X shape. In the X shape, the dimension in the Y direction, which corresponds to the row interval, and the dimension in the X direction, which corresponds to the column interval, are different from each other. As a result, it is possible to reduce the footprint of the process module and share the wafer transfer mechanism.

According to the embodiment, the process module further includes the deviation detection sensor 31a or 31b configured to detect the deviation of the wafer W at each of rotationally symmetric positions within the row interval or the column interval on a rotation trajectory of the wafer W held by the rotation arm 3. As a result, it is possible to correct the deviations of the wafers W at the time of transferring the wafers by the rotation arm 3.

According to the embodiment, each of the four stages 22 is finely movable in at least an XY plane according to the position of the wafer W detected by the deviation detection sensor. As a result, it is possible to correct the deviation of the wafer W, which is caused during the transfer or the like performed by the rotation arm 3.

According to the embodiment, two wafers W placed on the stages 22 in the same column can be transferred simultaneously. As a result, a two-wafer-type substrate processing apparatus and the wafer transfer mechanism can be communalized.

According to the embodiment, the substrate processing system 1 includes the plurality of process modules (the substrate processing apparatuses 2 and 2a) connected to the vacuum transfer chamber 14a or 14b equipped with the wafer transfer mechanism (the substrate transfer mechanism 15a or 15b). Each of the plurality of process modules includes four stages arranged in a two-row and two-column layout therein. In each of the plurality of process modules, a pitch in the Y direction between the stages of the layout, which is a direction along a surface facing the vacuum transfer chamber 14a or 14b, is the same between one process module and another process module among the plurality of process modules. A pitch in the X direction between the stages of the layout, which is a direction perpendicular to the surface facing the vacuum transfer chamber 14a or 14b, differs between one process module and the another process module. As a result, it is possible to make process modules having different footprints coexist, and share the wafer transfer mechanism.

According to the embodiment, in the processing method used in the process module (the substrate processing apparatus 2), the process module includes: the four stages 22 arranged therein in a two-row and two-column layout, wherein the row interval and the column interval constituting the layout have different dimensions; and the rotation arm 3 including four end effectors 32, each of which is capable of holding the wafer W to be placed on each of the four stages 22, and the base member 33 having the rotation shaft located at the center position of the layout, wherein the four end effectors 32 are connected to the base member 33 to form an X shape. In the X shape, the dimension in the Y direction, which corresponds to the row interval, and the dimension in the X direction, which corresponds to the column interval, are different from each other. In the processing method, by transferring the wafers W in a first column and a second column to be exchanged with each other by the rotation arm 3, different processes are repeated in the first column and the second column. As a result, it is possible to reduce the time required to transfer the wafers W between respective processes.

It shall be understood that the embodiments disclosed herein are illustrative and are not limiting in all aspects. The above-described embodiments may be omitted, replaced, or modified in various forms without departing from the scope and spirit of the appended claims.

For example, in the embodiments described above, an example in which the substrate processing apparatus 2 is an apparatus that performs a plasma CVD process as substrate processing has been described, but the technique disclosed herein may be applied to any apparatus that performs other substrate processing such as plasma etching.

In addition, in the above-described embodiments, the direct drive motor 348 is used as a constituent element that drives the rotor 343 in the biaxial vacuum seal 34, but the present disclosure is not limited thereto. For example, the rotor 343 may be provided with a pulley and may be driven using a timing bell from a motor provided outside the biaxial vacuum seal 34.

According to the present disclosure, it is possible to reduce an increase in footprint of a process module and a substrate processing system.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A process module comprising:
four stages arranged in a two-row and two-column layout inside the process module,
wherein a row interval and a column interval that constitute the two-row and two-column layout have different dimensions.

2. The process module of claim 1, further comprising:
a rotation arm including four end effectors, each of which is configured to hold a wafer to be placed on each of the four stages, and a base member including a rotation shaft located at a center position of the two-row and two-column layout, wherein the four end effectors are connected to the base member to form an X shape and, in the X shape, a dimension in a Y direction, which corresponds to the row interval, and a dimension in an X direction, which corresponds to the column interval, are different from each other.

3. The process module of claim 2, further comprising:
a deviation detection sensor configured to detect a deviation of the wafer at each of rotationally symmetric positions within the row interval or within the column interval on a rotation trajectory of the wafer held by the rotation arm.

4. The process module of claim 3, wherein each of the four stages is configured to finely move in at least an XY plane according to a position of the wafer detected by the deviation detection sensor.

5. The process module of claim 4, wherein two wafers placed on two stages located in a same column among the four stages are loaded into or unloaded from the process module.

6. The process module of claim 2, wherein two wafers placed on two stages located in a same column among the four stages are loaded into or unloaded from the process module.

7. The process module of claim 3, wherein two wafers placed on two stages located in a same column among the four stages are loaded into or unloaded from the process module.

8. A substrate processing system comprising:
a plurality of process modules connected to a vacuum transfer chamber including a wafer transfer mechanism,
wherein each of the plurality of process modules includes four stages arranged in a two-row and two-column layout, and
a Y-direction pitch between two stages of the four stages arranged in the two-row and two-column layout in a direction along a surface facing the vacuum transfer chamber is same between a first process module and a second module among the plurality of process modules, and an X-direction pitch between two stages of the four stages arranged in the two-row and two-column layout in a direction perpendicular to the surface facing the vacuum transfer chamber differs between the first process module and the second process module.

9. A processing method used in a process module,
wherein the process module includes:
four stages arranged in a two-row and two-column layout inside the process module, wherein a row interval and a column interval that constitute the two-row and two-column layout have different dimensions; and
a rotation arm including four end effectors configured to hold wafers to be respectively placed on the four stages, and a base member including a rotation shaft located at a center position of the two-row and two-column layout, wherein the four end effectors are connected to the base member to form an X shape and, in the X shape, a dimension in a Y direction, which corresponds to the row interval, and a dimension in an X direction, which corresponds to the column interval, are different from each other.
the processing method comprising:
transferring the wafers located in a first column and a second column in the two-row and two-column layout to be exchanged with each other by the rotation arm, so that different processes are repeated in the first column and the second column.
